(19) United States
(12) Patent Application Publication
(10) Pub. No.: US 2005/0125764 A1
(43) Pub. Date: Jun. 9, 2005

(54) Method for producing a mask layout avoiding imaging errors for a mask

(76) Inventor: Armin Semmler, Munchen (DE)

Correspondence Address: SLATER & MATSIL LLP, 17950 PRESTON ROAD, SUITE 1000, DALLAS, TX, 75252, US

(21) Appl. No.: 10/988,440

(22) Filed: Nov. 12, 2004

(30) Foreign Application Priority Data
Nov. 13, 2003 (DE) 103 53 798.8

(51) Int. Cl. G06F 17/50; G21K 5/00; G03F 9/00

(52) U.S. Cl. 716/21; 378/35; 430/5

(57) ABSTRACT

A method for producing a final mask layout avoids imaging errors. A provisional auxiliary mask layout that has been produced in accordance with a predetermined electrical circuit diagram is converted into the final mask layer with the aid of an OPC method. Before the OPC method is carried out, a modified auxiliary mask layout is formed with the provisional auxiliary mask layout by a procedure in which, in a first modification step, the mask structures of the provisional auxiliary mask layout are enlarged or reduced in size to form altered mask structures in accordance with a predetermined set of rules. Then the altered mask structures are supplemented, in accordance with predetermined positioning rules, by optically non-resolvable auxiliary structures to form the modified auxiliary mask layout. The mask layout is produced by the OPC method using the modified auxiliary mask layout.

This application claims priority to German Patent Application 103 53 798.8, which was filed Nov. 13, 2003 and is incorporated herein by reference.

1. Technical Field

The invention relates to a method for producing a mask layout avoiding imaging errors for a mask.

2. Background

It is known that, in lithography methods, imaging errors can occur if the structures to be imaged become very small and have a critical size or a critical distance with respect to one another. The critical size is generally referred to as the “CD” value (CD: Critical dimension).

What is more, imaging errors may occur if structures are arranged very closely next to one another. These imaging errors based on “proximity effects” can be reduced by modifying the mask layout beforehand with regard to the “proximity phenomena” that occur. Methods for modifying the mask layout with regard to avoiding proximity effects are referred to by experts by the term OPC methods (OPC: Optical proximity correction).

FIG. 1 illustrates a lithography process without OPC correction. The illustration reveals a mask 10 with a mask layout 20 that is intended to produce a desired photoresist structure 25 on a wafer 30. The mask layout 20 and the desired photoresist structure 25 are identical in the example in accordance with FIG. 1. A light beam 40 passes through the mask 10 and also a focusing lens 50 arranged downstream and falls onto the wafer 30, thereby imaging the mask layout 20 on the wafer 30 coated with photoresist. On account of proximity effects, imaging errors occur in the region of closely adjacent mask structures with the consequence that the resulting photoresist structure 60 on the wafer 30 in part deviates considerably from the mask layout 20 and thus from the desired photoresist structure 25. The photoresist structure that results on the wafer 30, the resulting photoresist structure being designated by the reference symbol 60, is illustrated in enlarged fashion and schematically beneath the wafer 30 for improved illustration in FIGS. 1 and 2.

In order to avoid or to reduce these imaging errors, it is known to use OPC methods that modify the mask layout 20 beforehand in such a way that the resulting photoresist structure 60 on the wafer 30 corresponds to the greatest possible extent to the desired photoresist structure 25.

FIG. 2 shows a previously known OPC method described in the document “A little light magic” (Frank Schellenberg, IEEE Spectrum, September 2003, pages 34 to 39, which paper is incorporated herein by reference), in which the mask layout 20′ is altered compared with the original mask layout 20 in accordance with FIG. 1. The modified mask layout 20′ has structure alterations which are smaller than the optical resolution limit and therefore cannot be imaged “1:1”. These structure alterations nevertheless influence the imaging behavior of the mask, as can be discerned at the bottom of FIG. 2; this is because the resulting photoresist structure 60 corresponds distinctly better to the desired photoresist structure 25 than is the case with the mask in accordance with FIG. 1.

In the case of the previously known OPC methods by which a “final” mask layout (c.f., mask 20′ in accordance with FIG. 2) is formed from a provisional auxiliary mask layout (e.g., the mask layout 20 in accordance with FIG. 1), a distinction is made between so-called “rule-based” and “model-based” OPC methods.

In the case of rule-based OPC methods, the formation of the final mask layout is carried out using rules, in particular tables, defined beforehand. The method disclosed in the two U.S. Pat. Nos. 5,821,014 and 5,242,770, both of which are incorporated herein by reference, by way of example, may be interpreted as a rule-based OPC method, in the case of which optically non-resolvable auxiliary structures are added to the mask layout according to predetermined fixed rules, in order to achieve a better adaptation of the resulting photoresist structure (reference symbol 60 in accordance with FIGS. 1 and 2) to the desired photoresist structure (reference symbols 25 in accordance with FIGS. 1 and 2). In the case of these methods, then, a mask optimization is carried out according to fixed rules.

In model-based OPC methods, a lithography simulation method is carried out, in the course of which the exposure operation is simulated. The simulated resulting photoresist structure is compared with the desired photoresist structure, and the mask layout is buried or modified iteratively until a “final” mask layout is present, which achieves an optimum correspondence between the simulated photoresist structure and the desired photoresist structure. The lithography simulation is carried out with the aid of a, for example, DP-based lithography simulator that is based on a simulation model for the lithography process. For this purpose, the simulation model is determined beforehand by “fitting” or adapting model parameters to experimental data. The model parameters may be determined for example by evaluation of so-called OPC curves for various CD values or structure types. One example of an OPC curve is shown in FIG. 6 and will be explained in connection with the associated description of the figures. Model-based OPC simulators or OPC simulation programmes are commercially available. A description is given of model-based OPC methods for example in the article “Simulation-based proximity correction in high-volume DRAM production” (Werner Fischer, Ines Anke, Giorgio Schweeger, Jörg Thiele; Optical Microlithography VIII, Christopher J. Progler, Editor, Proceedings of SPIE VOL. 4000 (2000), pages 1002 to 1009) and in the German patent specification DE 101 33 127 C2, which is incorporated herein by reference.

### SUMMARY OF THE INVENTION

In one aspect, the invention provides an improved method of the type specified in the introduction to the effect that imaging errors as a result of proximity effects are reduced even better than before.

In the first embodiment, a provisional auxiliary mask layout that has been produced in accordance with a predetermined electrical circuit diagram is converted into the final mask layer with the aid of an OPC method. Before the OPC method is carried out, a modified auxiliary mask layout is formed with the provisional auxiliary mask layout by a procedure in which, in a first modification step, the mask structures of the provisional auxiliary mask layout are enlarged or reduced in size to form altered mask structures in accordance with a predetermined set of rules. Then the altered mask structures are supplemented, in accordance with predetermined positioning rules, by optically non-resolvable auxiliary structures to form the modified auxiliary mask layout. The mask layout is produced by the OPC method using the modified auxiliary mask layout. Advantageous refinements of the method according to the invention are provided in the specification and drawings.

Accordingly, it is provided according to the invention that, before the “actual” OPC method is carried out, firstly a modified auxiliary mask layout is formed from the provisional auxiliary mask layout. For this purpose, in a first modification step, the mask structures of the provisional auxiliary mask layout are enlarged, in particular widened, or reduced in size to form altered mask structures in accordance with a predetermined set of rules. The altered mask structures are subsequently supplemented, in accordance with predetermined positioning rules, by non-resolvable auxiliary structures to form the modified auxiliary mask layout. After, the modified auxiliary mask layout is then subjected to the “actual” OPC method, in the course of which the final mask layout is then formed.

A first advantage of a method according to embodiments of the invention is that this method achieves a larger process window for carrying out the lithography method than is the case with the previously known OPC methods without the two modification steps according to the invention—i.e., without enlarging or reducing the size of the mask structures and without subsequent positioning of optically non-resolvable auxiliary structures.

A second advantage of a method according to embodiments of the invention is to be seen in the fact that the optically non-resolvable auxiliary structures can be arranged at a greater distance from the assigned main structures than is the case for example with the rule-based OPC method with optical auxiliary structures that is disclosed in the U.S. patent specifications mentioned in the introduction. Therefore, fewer hard mask specifications are to be complied with regard to the non-resolvable optical auxiliary structures; moreover, there is a reduced probability of the auxiliary structures being imaged undesirably under unfavorable conditions.

A third advantage of a method according to embodiments of the invention is to be seen in the fact that the lithography method is also possible in “overexposure”, thereby reducing the probability of auxiliary structures being imaged undesirably under unfavorable conditions. In particular, fluctuations in the structure widths over the entire mask (CD uniformity) are transferred to the wafer to a lesser extent, which is reflected in a low MEEF (mask error enhancement factor) value. In addition, the auxiliary structures may be wider than in the case of the previously known correction method described in the U.S. patent specifications mentioned in the introduction, so that the “process window” is enlarged in this respect, too. The masks thus become easier to produce and less expensive.

A fourth advantage of a method according to embodiments of the invention is that, on account of the enlargement of the process window, in addition the dependence of the CD value on the main structure is lower than otherwise, so that photoresist structures that can be produced with the mask react less to process and target fluctuations. This also relates, in particular, to the etching process following the photoresist development, since OPC is often employed after the etching step in the gate contact-connection plane. In other words, the OPC correction is effected in such a way that the CD corresponds to the design value after etching. In this case, the term “target” is understood to mean the structure size of the main structures to be imaged.

A fifth advantage of a method according to embodiments of the invention is to be seen in the fact that, on account of the enlargement or reduction in size of the mask structures and as a result of the addition of the optical auxiliary structures, already such a distinct improvement in the imaging behavior of the mask is achieved that generally the processing times in the subsequent OPC step are significantly reduced, namely because the deviations between the resulting photoresist structure and the desired photoresist structure are already greatly reduced by the “preoptimization”.

An advantageous refinement of the method according to the invention provides for a model-based OPC method to be carried out as the OPC method—this therefore means the main optimization method to be carried out after the pre-optimization. The advantage of a model-based OPC method (or OPC simulation programme) over a rule-based OPC method is that only relatively few measurement data have to be recorded in order to be able to determine the model parameters required for the method; afterward, virtually arbitrary structures can then be simulated. In contrast to this, in the case of a rule-based OPC method, comparatively extensive test measurements on the basis of structures that have really been produced are necessary in order to be able to establish the tables or rules required for carrying out the rule-based OPC method.

With regard to the enlargement or reduction in size of the mask structures—this modification step is referred to hereinafter for short as “pre-bias step”—it is regarded as advantageous if the set of rules to be employed is stored in the form of a table and the extent of enlargement or reduction in size—that is to say the “pre-bias”—is read from the table for each mask structure of the provisional auxiliary mask layout. On account of the “pre-bias” values being stored in a table, the pre-bias method step can be carried out very rapidly.

In this case, the discretization of the table values or of the table (=difference between the successive table values) is preferably identical to the discretization of the grid structure (=distance between the grid points) used in the subsequent OPC method, in order to enable an optimum further processing of the structure changes produced in the pre-bias step in the subsequent OPC method. As an alternative, the discretization of the table may also be twice as large as the discretization of the grid structure used in the OPC method, for example when the lines are intended to be “biased” (=enlarged or reduced in size) symmetrically with respect to their line center, since the bias effect respectively always occurs doubly in such a case.

As an alternative to a set of rules stored in the form of a table, the set of rules may also be stored in a mathematical function, the extent of enlargement or reduction in size—that is to say the pre-bias—of the mask structures of the provisional auxiliary mask layout being calculated for each of the mask structures with the aid of the mathematical function.

Preferably, the set of rules defines the extent of the enlargement or reduction in size of the mask structures of the provisional auxiliary mask layout in two-dimensional form, so that actually two-dimensional geometrical design structures can be taken into account.

Moreover, the set of rules takes account of mask structures having dimensions in the CD range separately by defining CD classes with, in each case, a minimum and maximum structure size, and wherein an identical set of rules is employed within each CD class.

Moreover, the set of rules may provide additional rules to be applied to line ends and contact holes. By way of example, line ends or contact holes are lengthened or shortened or rounded or serif-like structures or so-called hammerheads are added.

Moreover, the set of rules may deal differently with mask structures that represent wirings and those that define the gate or the gate length of transistors, by virtue of the fact that different sets of rules are employed in each case therefor.

In addition, the set of rules preferably also takes into account, besides the CD value, the distance between the main structures of the provisional auxiliary mask layout by using a two-dimensional bias matrix, that is to say a bias matrix dependent on the CD value and on the distance.

The set of rules used are determined either experimentally on the basis of test structures or by means of lithography simulation.

When positioning the optically non-resolvable auxiliary structures, the latter may furthermore be varied in terms of their width or in terms of their distances with respect to one another and/or with respect to the adjacent main structures. In this regard, it is possible to have recourse for example to the positioning rules described in detail in the US patent specifications mentioned in the introduction.

The method according to the invention can be carried out particularly simply and rapidly by means of a DP system or by means of a computer.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates a system for use in a lithography process without OPC correction;

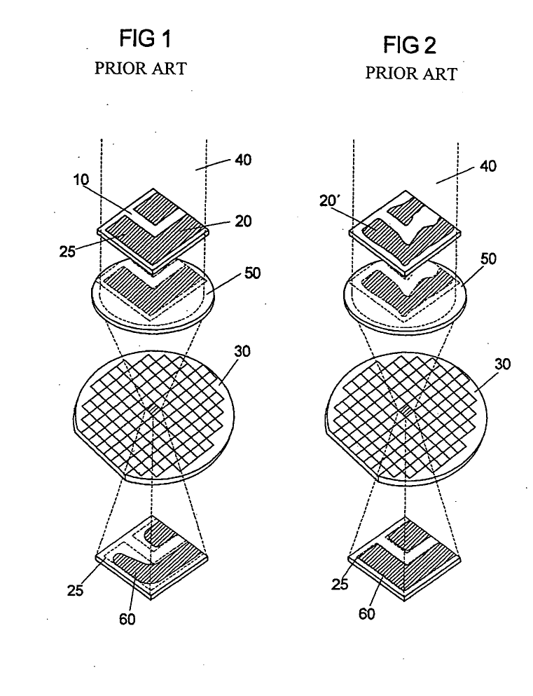

FIG. 2 illustrates a system for use in a lithography process with OPC correction;

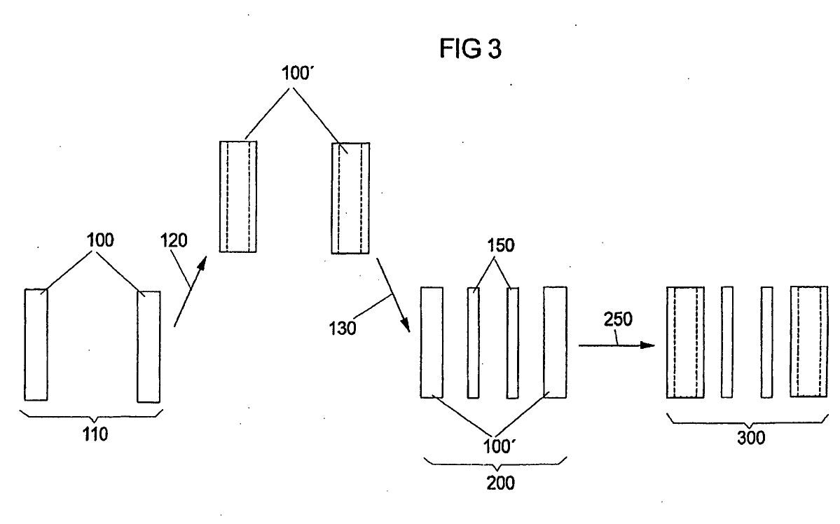

FIG. 3 schematically shows mask structures on the basis of which the implementation of a method according to embodiments of the invention is elucidated by way of example;

FIG. 4 shows an illustration of a “simple” variant of a method according to embodiments of the invention;

FIG. 5 shows an improved variant of a method according to embodiments of the invention compared with the “simple” variant;

FIG. 6 shows an illustration of the dependence of the CD value on the distance between the mask structures among one another; and

FIGS. 7 to 9 show the process window enlargement that results on account of a method according to embodiments of the invention using the example of target dimensions of 115 nm, 130 nm and 145 nm.

The following list of reference symbols can be used in conjunction with the figures:

10 Mask

20 Mask layout

20′ Modified mask layout

25 Photoresist structure

30 Wafer

40 Light beam

50 Focusing lens

60 Resulting photoresist structure

100 Lines

110 Provisional auxiliary mask layout

110′ Widened lines

120 Pre-bias step

130 SRAF positioning step

150 SRAF structures

200 Modified auxiliary mask layout

250 OPC method

300 Final mask layout

600 OPC line

610 Isolated lines

620 Average, semi-dense main structures

630 Very dense structures

700 Process window with optimization

700′ Process window without optimization

710 Bias line

720 No-bias line

### DETAILED DESCRIPTION OF ILLUSTRATIVE EMBODIMENTS

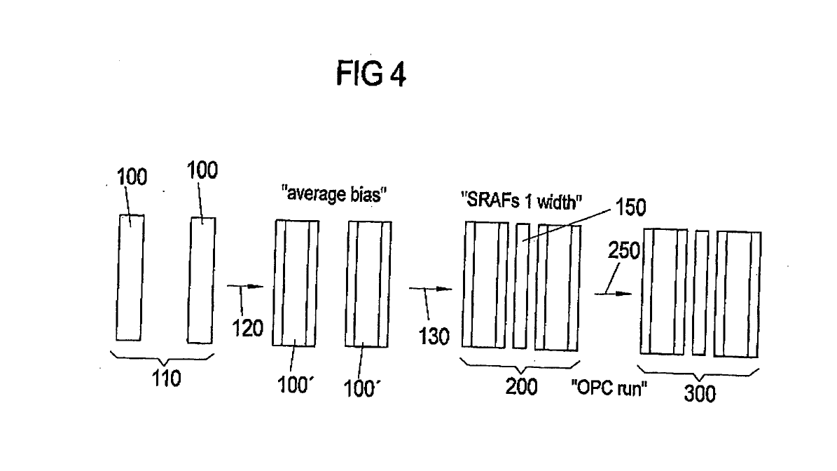

FIG. 3 reveals a provisional auxiliary mask layout 110 formed by way of example by two vertical lines 100, which is altered in a first modification step—called pre-bias step 120 hereinafter—by widening the two lines 100 of the provisional auxiliary mask layout 110. Widened lines 100′ arise in this case.

In a subsequent processing step 130, optically non-resolvable auxiliary structures—also called SRAF (sub resolution assist feature) structures—150 are placed between the two widened lines 100′, thereby forming a modified auxiliary mask layout 200. The processing step 130 may thus be referred to as “SRAF positioning step”.

The modified auxiliary mask layout 200 is subsequently subjected to an OPC method 250, by means of which the modified auxiliary mask layout 200 formed by the widened lines 100′ and the non-resolvable auxiliary structures 150 is altered further in such a way that a final mask layout 300 arises. The final mask layout 300 has a largely optimum imaging behavior. In this case, an optimum imaging behavior is understood to mean that proximity effects on account of the close proximity between the two main lines 100 and 100′, respectively, cause no or only slight imaging errors.

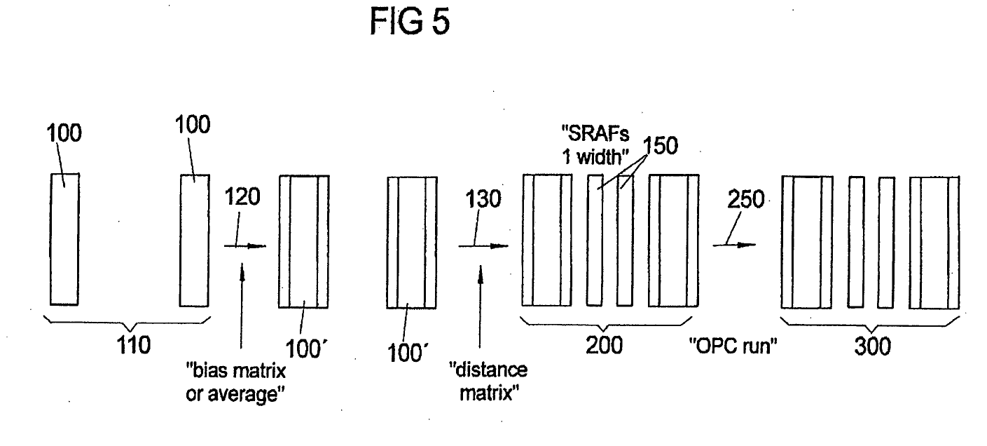

A particularly “simple” exemplary embodiment of the method according to the invention is indicated in FIG. 4. In the case of this method, the pre-bias step 120 is carried out in accordance with a “simple” set of rules. This means that each structure, that is to say each of the two lines 100, is biased or enlarged in accordance with a fixedly predetermined average value (“average bias”=average enlargement or size reduction).

The optically non-resolvable auxiliary structures 150 are positioned 130 without taking account of the CD value of the assigned main structure by the addition of SRAF structures 150 exclusively having one and the same structure size (“SRAFs 1 width”=SRAF structures having a single width).

In the case of the method in accordance with FIG. 4, the structure-dependent CD values and the concrete two-dimensional structure of the main structure formed by the two lines 100 are thus left out of consideration.

In the subsequent model-based OPC step (“OPC run”) 250, the final mask layout 300 is then formed from the modified auxiliary mask layout 200.

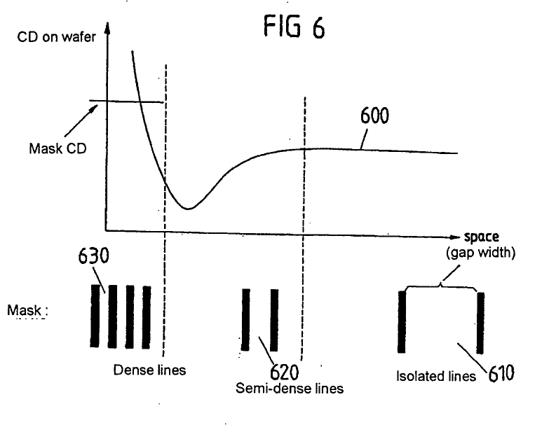

FIG. 5 shows an “improved” variant of a method according to embodiments of the invention compared with the exemplary embodiment in accordance with FIG. 4. In the case of this method, the CD value of the main structure formed by the two widened lines 100′ and also the distance between the optical auxiliary structures 150 and the two widened lines 100′ are taken into account during the positioning of the non-resolvable SRAF auxiliary structures (step 130). This is symbolized in FIG. 5 by the expression (“distance matrix”).

In this case, the width of the optically non-resolvable auxiliary structures 150 may be chosen to be constant (“SRAFs 1 width”) or else structure-dependent.

Moreover, in the case of the exemplary embodiment in accordance with FIG. 5, the pre-bias step 120 is carried out in such a way that the CD values and the structure of the two lines 100 are taken into account. By way of example, the set of rules may take account of mask structures having dimensions in the CD range by defining CD classes having in each case a maximum and a minimum structure size, an identical set of rules or a constant enlargement or reduction in size of the main structure being carried out in each CD class. Moreover, the set of rules may provide for line ends and contact holes to be subjected to additional rules; by way of example, line ends or contact holes may be lengthened or shortened, or rounded, or serif-like structures or so-called hammerheads may be added. This variant of the pre-bias step 120 is identified in FIG. 5 by the term “bias matrix or average” (=enlargement or size reduction matrix or average enlargement or size reduction).

With the modified auxiliary mask layout 200 formed in this way, the model-based OPC method 250 is then carried out, which may correspond to the OPC method already described in FIGS. 3 and 4.

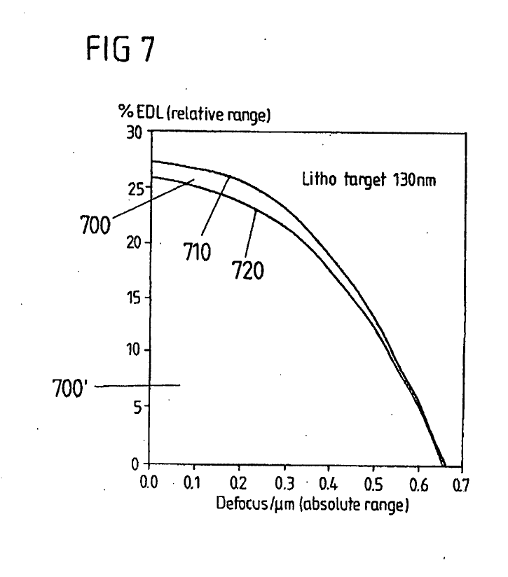

FIG. 6 illustrates an OPC curve 600 specifying how the CD values vary in a manner dependent on the distance between the main structures, for example thus in the case of lines. In the case of isolated lines 610, the CD value is largely independent of the distance between the structures. In the case of average, semi-dense main structures 620, the CD value falls in the direction of smaller structure distances before it rises significantly again in the case of very dense structures 630.

In this case, the OPC curve 600 describes the CD value profile on the wafer given a constant mask CD value, which is likewise depicted in FIG. 6 for comparison.

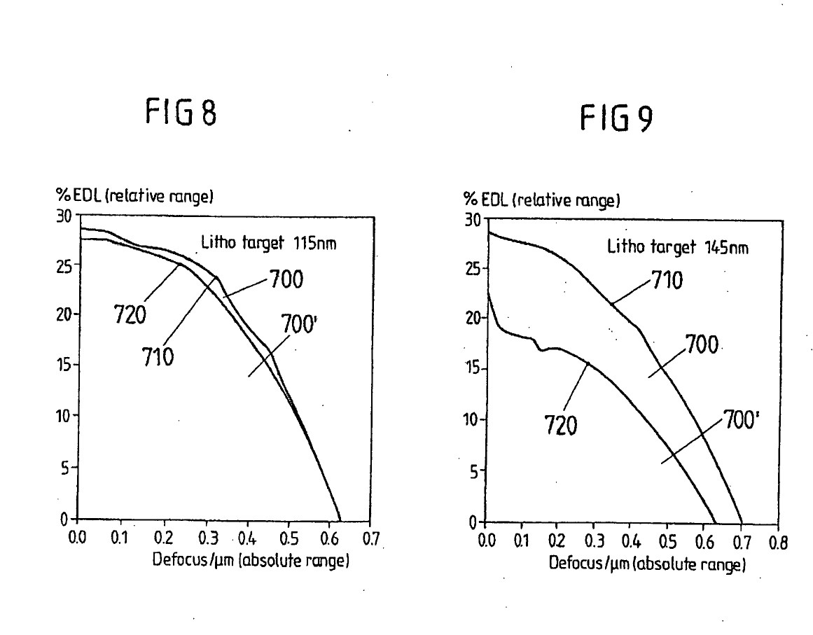

In FIGS. 7, 8 and 9, two process windows 700 and 700′ are plotted as a relationship between the percentage fluctuation of the exposure dose (EDL=exposure dose latitude) and defocus value in micrometers. A fluctuation of the CD of +/−10% from the nominal value is assumed in the case of the permissible fluctuation of the exposure dose. Outside the process window ranges 700 and 700′, respectively, the imaging errors in each case exceed predetermined error limits; the lithographically usable process region corresponds to the area beneath the curves.

The process window 700 is bounded by a “bias” line 710 and the coordinate axes and the process window 700′ is bounded by a “no-bias” line 720 and the coordinate axes.

The “bias” line 710 defines the process window for the case where a mask optimization is carried out in accordance with the method explained in connection with FIG. 5, that is to say including pre-bias step 120 and SRAF positioning step 130.

The “no-bias” line 720 defines the process window 700′ for the case where a mask optimization is carried out only by means of an OPC method—that is to say without prior optimization of the mask structure.

It can be gathered from FIGS. 7, 8 and 9 that, at target structure sizes (“litho target”) of 115 nm (FIG. 8), 130 nm (FIG. 7) and 145 nm (FIG. 9), a significantly larger process window 700 is achieved if the described method according to embodiments of the invention with a modification of the auxiliary mask layout is carried out. Otherwise—when only a previously known OPC method is carried out—only a smaller process window 700′ can be achieved, by contrast.

1. A method for producing a final mask layout avoiding imaging errors for a mask, the method comprising:
converting a provisional auxiliary mask layout that has been produced in accordance with a predetermined electrical circuit diagram into the final mask layer with the aid of an OPC method; wherein:
before the OPC method is carried out, firstly a modified auxiliary mask layout is formed with the provisional auxiliary mask layout;
by a procedure in which, in a first modification step, mask structures of the provisional auxiliary mask layout are enlarged or reduced in size to form altered mask structures in accordance with a predetermined set of rules;
then the altered mask structures are supplemented, in accordance with predetermined positioning rules, by optically non-resolvable auxiliary structures to form the modified auxiliary mask layout; and
the mask layout is produced by the OPC method using the modified auxiliary mask layout.

2. The method as claimed in claim 1, wherein a model-based OPC method is carried out as the OPC method.

3. The method as claimed in claim 1, wherein the predetermined set of rules is stored in the form of a table and an extent of enlargement or size reduction of the mask structures of the provisional auxiliary mask layout is read from the table for each of the mask structures.

4. The method as claimed in claim 3, wherein a discretization of the table is identical to a discretization of a grid structure used in the OPC method.

5. The method as claimed in claim 3, wherein a discretization of the table is twice as large as a discretization of a grid structure used in the OPC method.

6. The method as claimed in claim 3, wherein the predetermined set of rules is stored in a mathematical function and an extent of enlargement or size reduction of the mask structures of the provisional auxiliary mask layout is calculated for each of the mask structures with the aid of the mathematical function.

7. The method as claimed in claim 1, wherein the predetermined set of rules defines an extent of enlargement or size reduction of the mask structures of the provisional auxiliary mask layout in two-dimensional form.

8. The method as claimed in claim 1, wherein the predetermined set of rules takes account of mask structures having dimensions in the CD (critical dimension) range separately by defining CD classes with in each case a minimum and maximum structure size, and wherein an identical set of rules is employed within each CD class.

9. The method as claimed in claim 8, wherein, in addition to the CD value, the distance between main structures of the provisional auxiliary mask layout is also taken into account by the predetermined set of rules by virtue of the use of a two-dimensional bias matrix, the two-dimensional bias matrix being dependent on the CD value and on the distance.

10. The method as claimed in claim 1, wherein the predetermined set of rules provides additional rules for line ends and contact holes.

11. The method as claimed in claim 10, wherein line ends or contact holes are lengthened or shortened or rounded.

12. The method as claimed in claim 10, wherein serif-like structures or hammerheads are added to line ends or contact holes.

13. The method as claimed in claim 1, wherein the predetermined set of rules deals differently with mask structures that represent wirings and those that define gates.

14. The method as claimed in claim 1, wherein the predetermined positioning rules take account of auxiliary structures having variable width and variable distances among one another and/or with respect to the adjacent main structures.

15. The method as claimed in claim 1, wherein the application of the set of rules is carried out by means of a DP system.

16. A method for producing a mask, the method comprising:
determining a provisional mask layout in accordance with a predetermined electrical circuit diagram, the provisional mask layout including substantially rectangular shaped mask structures;
modifying a width of at least some of the substantially rectangular shaped mask structures of the provisional mask layout in accordance with a predetermined set of rules to form altered mask structures;
supplementing the altered mask structures, in accordance with predetermined positioning rules, by including optically non-resolvable auxiliary structures to form a modified mask layout; and
producing a mask layout based upon the modified mask layout using an OPC (optical proximity correction) method.

17. A method of manufacturing a semiconductor device, the method comprising:
determining an electrical circuit;
determining a provisional mask layout in accordance with the predetermined electrical circuit diagram, the provisional mask layout including substantially rectangular shaped mask structures;
modifying a width of at least some of the substantially rectangular shaped mask structures of the provisional mask layout in accordance with a predetermined set of rules to form altered mask structures;
supplementing the altered mask structures, in accordance with predetermined positioning rules, by including optically non-resolvable auxiliary structures to form a modified mask layout;
producing a mask based upon the modified mask layout; and
fabricating a semiconductor device using the mask.

18. The method of claim 17 wherein fabricating a semiconductor device comprises:
providing a wafer that is coated with photoresist; and
passing a beam through the mask so that the beam falls onto the wafer.

19. The method of claim 17 wherein modifying a width comprises widening at least some of the substantially rectangular shaped mask structures.

20. The method of claim 17 wherein modifying a width comprises narrowing at least some of the substantially rectangular shaped mask structures.

21. The method of claim 17 wherein the predetermined set of rules is stored in the form of a table and the width of the mask structures is modified based upon the table.

22. The method of claim 21, wherein a discretization of the table is identical to a discretization of a grid structure of the mask.

23. The method of claim 21 wherein a discretization of the table is twice as large as a discretization of a grid structure of the mask.

24. The method of claim 17 wherein the predetermined set of rules comprises a mathematical function.

25. The method of claim 17, wherein the predetermined set of rules comprises a plurality of subsets of rules, each subset being used for mask structures having dimensions within a range.

26. The method of claim 17, wherein the predetermined set of rules provides additional rules for line ends and contact holes.

27. The method of claim 17, wherein the predetermined set of rules comprises a two-dimensional bias matrix that is dependent on a critical dimension value and on a distance between adjacent structures.
